(19) United States
(12) Patent Application Publication
(10) Pub. No.: US 2007/0037100 A1
(43) Pub. Date: Feb. 15, 2007

(54) High aspect ratio mask open without hardmask

(75) Inventors: Johnathan E. Falterrneier, Fishkill, NY (US); Yuko Lisa Ninomiya, Ridgefield, CT (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 11/161,604

(22) Filed: Aug. 9, 2005

(51) Int. Cl. G03F 7/26

(52) U.S. Cl. 430/313; 430/311; 430/316

(57) ABSTRACT

A method of etching a stack of dielectric mask layers by reactive ion etch steps in order to open an aperture for etching into a semiconductor substrate improves the selectivity of the reactive ion etch relative to photoresist to the extent that an etch of an equivalent of 2000 nm of oxide is made with only photoresist as the etch mask, instead of a hardmask, thereby permitting the etch to be performed in a single chamber of an etch tool.

### TECHNICAL FIELD

The field of the invention is that of etching in a reactive ion etch process, in particular increasing the selectivity of the etch process such that the etch attacks the dielectric or other material at a much greater rate than the photoresist.

### BACKGROUND OF THE INVENTION

Semiconductor processing has long used etching processes to attack an exposed dielectric or other material preferentially to an etch mask, such as a layer of photoresist.

The basic process is that a layer of material to be patterned (e.g. silicon oxide) is put down and a layer of photoresist is deposited, exposed with a pattern and developed to produce a pattern of exposed areas of the material and areas that are covered by the developed (and thereby made etch-resistant) resist.

The etchant is selected such that it attacks the material preferentially to the developed resist. The resist is chemically similar to synthetic rubber—i.e. it polymerizes, forming chains of linked molecules that are resistant to chemical attack by a chemical that does attack the material being patterned.

An advanced form of etching is referred to as reactive ion etching and uses RF power to separate the etching material into ions that react very strongly with the material, but do not attack the linked molecules to the same extent. This approach uses chemicals such as chlorine and fluorine that can be separated to form ions that are very reactive. The etch rate of this technique can be varied by varying the applied RF power to increase or decrease the number of available ions.

A fundamental property of photoresist is the type of radiation that initiates the linking process. Various recipes of resist vary in the wavelength of light that starts the process.

Currently, an established type of resist that is commonly used reacts to light of wavelength 248 nm, The next shortest available wavelength (i.e. having a wavelength that is readily produced) is 193 nm, available from Japan Synthetic Rubber.

Those skilled in the art are aware that the exposed and developed material of the 193 nm resist is much less resistant to attack by ions than is the correspondingly exposed and developed material of the 248 nm resist. For example, a layer of the same thickness of exposed 248 nm resist and of 193 nm resist will be reduced to ˜50% in the case of the 248 nm resist and to ˜30% in the case of the 193 nm resist, when both resists are exposed to a standard etch mixture containing Fluorocarbon chemistry such as CF4, CHF3, C4F6 etc. under the same conditions.

Another factor that affects the ability of a layer of resist to survive attack is the thickness of the resist. This thickness is influenced heavily by the dimension of the aperture being formed. It is well known to those skilled in the art that a focused beam of light has a waist of minimum diameter, preceded and followed by areas that are broader and that the minimum waist depends on the wavelength of the light that is used. There is a certain distance along the beam that will be within a tolerance range of the minimum waist. This distance sets the maximum thickness of the resist, since a thicker resist layer will have a minimum beam spot that is larger than the beam spot of a corresponding thinner layer. The shorter the wavelength, the thinner the resist has to be.

Thus, when the standard transverse dimension of a lithography feature shrank to a value less than what the 248 nm resist could provide, it became necessary to shift to 193 nm resist in a thinner layer. The 248 nm resist used layers of 600-1000 nm, while the 193 nm resist can only be used in layers of 450 nm or less. A thinner resist layer can withstand an etch for a shorter time and therefore can only be used with a thinner material to be patterned than a corresponding thicker resist layer.

According to the previous multi-tool hardmask process, the best selectivity between the film etch rate and the resist etch rate (about 5-6) was not high enough to use only resist as the etch mask; i.e. a hardmask was required.

The solution to a requirement of a thinner resist than is necessary for the etch has been found before in the art and is a hardmask. A hardmask is a relatively thin layer of an etch-resistant material that is deposited above the dielectric stack that is to be etched. The resist is patterned with the appropriate size exposure, the resist is developed and the hardmask is etched with an appropriate etch recipe that is effective to etch the hardmask. The remaining resist is then stripped, leaving the hardmask in place as the mask for the etching process that defines the dielectric stack.

Common hardmasks are polysilicon, nitride or TERA Tunable Etch-Resistant Anti-Reflective Coating), which may be used to etch stacks of oxide, since the etchant chemistry for oxide attacks poly or nitride only slowly.

Those skilled in the art are aware that hardmasks incur additional costs; i.e. the cost of a deposition tool and an additional RIE tool, the process time required to perform the RIE to pattern the hardmask, yield loss caused by particles introduced by the hardmask processing, yield loss caused by lack of uniformity in the various steps of the hardmask deposition, patterning and strip.

In a particular application, a deep trench is to be formed for the capacitor in a DRAM cell and a thick stack that forms the mask during the deep trench etch is to be patterned. The deep trench mask stack is nominally 300 nm of TERA hardmask, 1800 nm of boron-doped glass (BSG) and 210 nm of nitride.

The process is shown in FIG. 3, in which the TERA hard mask is deposited in a Applied Materials deposition tool; resist is deposited, exposed and developed; the TERA hardmask is etched in a Tokyo Electron Limited DRM etch tool using CHF3/N2 chemistry; the resist is stripped in a solvent; the BSG is etched with C4F6 chemistry in a Applied Materials Inc. (AMAT) EMAX RIE tool; the backside film is stripped in a Gasonics tool; the remaining TERA mask is stripped in a LAM TCP RIE tool; and the nitride layer is etched using CO, Ar, CH2F2 chemistry in an AMAT eMAX tool.

The result is a deposition of the hardmask and four RIE steps.

The art could benefit from a simpler process that performed some of the etching steps in the same tool and/or eliminated one or more of the etching steps as well as hard mask such as Poly or TERA.

### SUMMARY OF THE INVENTION

The invention relates to a method of opening an aperture in a dielectric stack containing at least oxide (optionally an ARC and nitride) in which all the etching steps are performed in the same tool.

A feature of the invention is that the etching is performed with only photoresist as an etch mask.

Another feature of the invention is a moderate overetch of the ARC, which produces an increase in etch selectivity to reduce the rate at which the etches attack the resist.

Yet another feature of the invention is the addition of a preliminary oxide etch, which produces a further increase in selectivity.

### BRIEF DESCRIPTION OF THE DRAWINGS

FIG. 1 shows an example of a dielectric stack processed according to the invention.

FIG. 2 shows a simplified drawing of an etch tool.

FIG. 3 shows steps in a prior art process.

### DETAILED DESCRIPTION

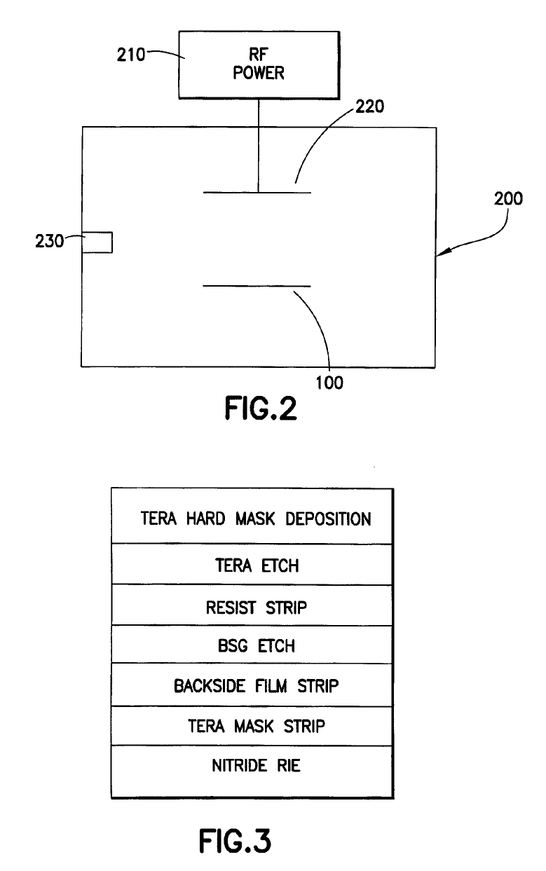

FIG. 2 illustrates, in partially pictorial, partially schematic fashion, an etching tool that may be used with the inventive process. The tool, denoted generally with numeral 200, encloses a vacuum chamber that is filled with a mixture of gases that are stimulated by RF power from generator 210 and that is fed to at least one RF electrode 220. Electrode 220 represents schematically the electrodes in the chamber. Some versions of etching tools have two or more electrodes that are positioned and fed different amounts of power to improve the uniformity of excitation of the etch molecules and/or the quantity of ions that are excited by the RF power.

On the left of the figure, nozzle 230 represents the gas distribution system that feeds in the active gases plus the carrier gas.

In operation, wafer 100, supported by a structure not shown for simplicity, may be heated by the RF and/or infra-red radiation from heat lamps. The ionized gas flows over the surface of the wafer to bring fresh gas into contact with the material to be etched.

Different manufactures may arrange their tools differently and this figure is meant to represent only the general features of such a tool.

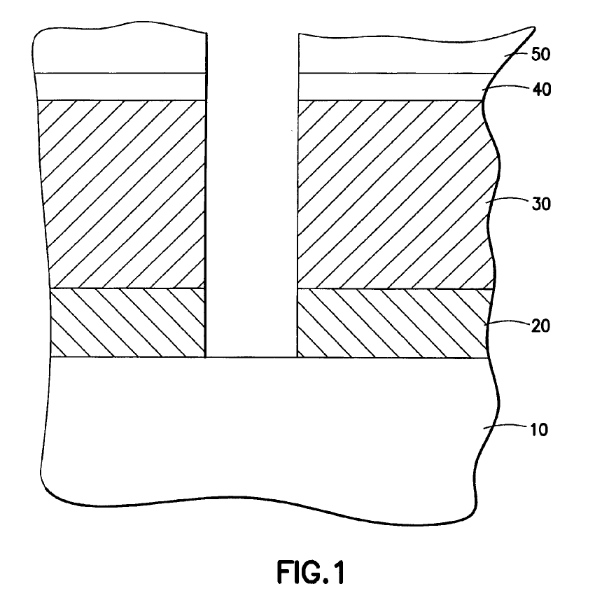

FIG. 1 shows a typical structure after the etching process is completed. Substrate 10 is the semiconductor wafer that is being processed in the fab. In this example, substrate 10 is silicon, but could be any other semiconductor.

The result of the entire process will be a deep trench in substrate 10 that will be part of a DRAM cell in an integrated circuit. The etch process of the deep trench is not part of the present invention, which is concerned with etching through a dielectric stack that forms the etch mask for the deep trench (or comparable structures of layers).

The stack comprises nitride 20, oxide 30 and anti-reflective coating (ARC) 40. Illustratively, nitride 20 is 210 nm thick, oxide 30 is 1,500 nm thick and ARC 40 (e.g. poly or TERA, which is required to stop the developing Photo resist to from developing further) is 65 nm thick.

In the past, as illustrated in FIG. 3, the etch processes for the oxide, nitride and TERA would be done in different etch tools.

FIG. 3 illustrates the prior art processes for the same stack of dielectric layers. The hardmask is TERA, which is also the anti-reflective coating. TERA (Tunable Etch-Resistance Anti-Reflective Coating) is a durable etch-resistant material that forms a good hardmask. Resist is deposited on the TERA and patterned with the desired aperture size. The TERA layer, nominally 300 nm thick, is etched in a TEL RIE tool using C4F8/O2/Ar/CHF3/N2 chemistry. The remaining resist after the TERA etch is stripped using a HF solvent.

With the TERA hardmask, the BSG was etched in an Applied Materials eMAX RIE chamber, using C4F6/Ar/O2 chemistry. After the BSG etch, a backside TERA film strip was done in a Gasonics tool using O2 chemistry.

Any remaining TERA hard mask was stripped at this time in an optional step that may not be required for all tools. In the BSG etch recommended by the manufacturer, the TERA is attacked at a relatively high rate, such that the BSG is used as a hard mask to etch the 210 nm nitride film. The nitride layer was etched using CO, Ar, CH2F2 chemistry in an emax tool.

Those skilled in the art will appreciate that this process uses four RIE processes in four tools, so that the cost of opening the aperture for the deep trench includes the cost of ownership of the four tools, plus the process time in the fab, plus additional yield detractors associated with handling the wafer in extra steps.

According to the present invention, the aperture for the deep trench is opened in a single operation in a single chamber of a tool (e.g. a Tokyo Electron Limited (TEL) SCCM Oxide etch tool). Instead of the traditional parallel plate one frequency and one power control, the TEL SCCM tool has top and bottom power (Source and Bias power) and two frequencies.

The tool may be a multi-chamber tool such as the SCCM, or by a specialized RIE tool. The choice of a multi-purpose tool or single-purpose tool will depend on the usual considerations and trade-offs in selecting a tool set for a fab.

According to the invention, the illustrative stack, including ARC, thick oxide and nitride, is etched in a single chamber of a tool, using different chemistry, RF power and other parameters adapted to increase the selectivity of the etch rate between the resist and the various films in the stack, so that the only etch mask is the resist.

According to the previous multi-tool hardmask process, the best selectivity between the film etch rate and the resist etch rate (about 5-6) was not high enough to use only resist as the etch mask; i.e. the hardmask was required.

The process according to the invention proceeds in the following steps:

After the stack has been formed, 400 nm of 193 nm resist is deposited and patterned.

1) The TERA ARC layer 40 is etched with a pressure of 15 mT, RF power in the upper Coil of 1800 W, RF power in the lower Coil of 100 W, and a flow rate of 100 sccm of H2. The illustrative thickness of 65 nm is etched for 75 seconds, including an overetch of about 25%, referred to as a moderate overetch.

2) The oxide 30 is etched in two steps. The first step is at a pressure of 25 mT, RF powers of 1500 W and 1500 W, 120 sccm of H2 and 80 sccm of CF4.

3) The second oxide step is 25 mT/1800 W/1150 W/21O2/550 Ar/20C4F6, in which the second etch step has an upper power more than 50% greater than the lower power.

4) In the case when a nitride layer is present, the nitride etch is 50 mT/1450 W/1350 W/15O2/300 Ar/35CH2F2/40CHF3.

At the end of the etch above, of the equivalent of 2000 nm of BSG, the thickness of the remaining resist was 285 nm, so that the ratio of etch rates was 17:1.

As a comparison, the ARC was composed of TERA, which is also used as a hardmask. In that case, with the same etch recipe, the amount of TERA remaining was 30 nm out of an initial 65 nm, for a ratio of etch rates of 57.

An advantageous feature of the invention is that the oxide etch rate is not noticeably different between low resist vs. high resist selectivity oxide etch process; i.e. the improved selectivity did not result in a slower etch rate.

The ARC etch rate according to the invention is slower, but the resist etch is also slower.

The nitride etch rate is also similar to the previous method, but the resist etch rate during the nitride etch is much slower.

The times and recipes used for the example are listed below:

1. ARC—75 sec/15 mT/1800 W/100 W/100H2

2. OX(1)—60 sec/25 mT/1500 W/1500 W/120H2/80CF4

3. OX(2)—180 sec/25 mT/1800 W/1150 W/21O2/550 Ar/20C4F6

4. SiN—0sec/50 mT/1450 W/1350 W/15O2/300 Ar/35CH2F2/40CHF3

The example used is the opening of the etch mask for a deep trench etch because that is the most challenging in current technology. Those skilled in the art will realize that the process can be used with oxide, nitride, or both as the stack being etched.

Since the process does not consume the entire resist layer, the etch resistance of the ARC does not matter, since it is not attacked during the etch.

Alternatively, if the final structure does not require the ARC to remain, the resist may be made thinner, so that the ARC functions also as a hardmask.

While the invention has been described in terms of a single preferred embodiment, those skilled in the art will recognize that the invention can be practiced in various versions within the spirit and scope of the following claims.

What is claimed is:

1. A method of etching a stack of an ARC layer plus at least one dielectric layer to open an aperture for a subsequent etch of said dielectric layer comprising the steps of:
depositing a layer of photoresist on said stack of at least one dielectric layer;
exposing said layer of photoresist with a pattern of apertures at a wavelength of 248 nm or less:
developing said photoresist to open a set of apertures therein, said set of apertures exposing said ARC layer while the remainder of said photoresist remains as an etch mask;
etching said ARC layer through said apertures; and
etching said stack of at least one dielectric layer by a two-step etching process in said set of apertures while said photoresist blocks said the etching of said stack outside said set of apertures, wherein said etching process is adapted such that the etch attacks the dielectric layers preferentially to the photoresist at an etch ratio of greater than 10.

2. A method according to claim 1, in which said step of etching said ARC layer includes a moderate overetch that increases the etch resistance of said photoresist.

3. A method according to claim 1, in which said at least one dielectric includes oxide and a first step of said two-step etching process is of shorter duration than a second step, both of said first and second steps attacking said oxide.

4. A method according to claim 2, in which said at least one dielectric includes oxide and a first step of said two-step etching process is of shorter duration than a second step, both of said first and second steps attacking said oxide.

5. A method according to claim 1, in which said at least one dielectric includes nitride.

6. A method according to claim 2, in which said at least one dielectric includes nitride.

7. A method according to claim 3, in which said at least one dielectric includes nitride.

8. A method according to claim 1, in which said at least one dielectric includes both oxide and nitride.

9. A method according to claim 1, in which upper RF power is applied to an upper electrode disposed above said stack and lower RF power is applied to a lower electrode disposed below said stack during the step of etching said ARC layer, the amount of said upper RF power being at least ten times the amount of said lower RF power.

10. A method according to claim 1, in which upper RF power is applied to an upper electrode disposed above said stack and lower RF power is applied to a lower electrode disposed below said stack during a first step of said two-step etching process, the amount of said upper RF power being substantially equal to the amount of said lower RF power.

11. A method according to claim 2, in which upper RF power is applied to an upper electrode disposed above said stack and lower RF power is applied to a lower electrode disposed below said stack during a first step of said two-step etching process, the amount of said upper RF power being substantially equal to the amount of said lower RF power.

12. A method according to claim 1, in which upper RF power is applied to an upper electrode disposed above said stack and lower RF power is applied to a lower electrode disposed below said stack during a second step of said two-step etching process, the amount of said upper RF power being substantially fifty percent greater than the amount of said lower RF power.

13. A method according to claim 2, in which upper RF power is applied to an upper electrode disposed above said stack and lower RF power is applied to a lower electrode disposed below said stack during a second step of said two-step etching process, the amount of said upper RF power being substantially fifty percent greater than the amount of said lower RF power.

14. A method according to claim 1, in which said step of etching said ARC layer and a first step of said two step etching process are performed in the same chamber of an etching tool.

15. A method according to claim 1, in which said step of etching said ARC layer and a first step and a second step of said two step etching process are performed in the same chamber of an etching tool.

16. A method according to claim 1, in which said two-step etching process etches a single layer of oxide;
said step of etching said stack includes a step of etching a layer of nitride; and
said step of etching said ARC layer, a first step and a second step of said two step etching process and a step of etching said layer of nitride are all performed in the same chamber of an etching tool.

17. A method according to claim 2, in which said step of etching said ARC layer and a first step of said two step etching process are performed in the same chamber of an etching tool.

18. A method according to claim 2, in which said step of etching said ARC layer and a first step and a second step of said two step etching process are performed in the same chamber of an etching tool.

19. A method according to claim 2, in which said two-step etching process etches a single layer of oxide;
said step of etching said stack includes a step of etching a layer of nitride; and
said step of etching said ARC layer, a first step and a second step of said two step etching process and a step of etching said layer of nitride are all performed in the same chamber of an etching tool.
